(19) United States
(12) Patent Application Publication
(10) Pub. No.: US 2024/0384147 A1
(43) Pub. Date: Nov. 21, 2024

(54) THERMALLY CONDUCTIVE COMPOSITION AND THERMALLY CONDUCTIVE SHEET

(71) Applicant: DEXERIALS CORPORATION, Tochigi (JP)

(72) Inventors: Yijing ZHAO, Tochigi (JP); Hiroki SHIBUYA, Tochigi (JP); Yuki IWATA, Tochigi (JP); Takeshi NISHIO, Tochigi (JP); Makoto INOUE, Tochigi (JP); Ryoko KAWAKAMI, Tochigi (JP)

(21) Appl. No.: 18/690,044

(22) PCT Filed: Aug. 22, 2022
(86) PCT No.: PCT/JP2022/031612

§ 371 Date: Mar. 7, 2024

(30) Foreign Application Priority Data
Sep. 9, 2021 (JP) 2021-146584
Jun. 3, 2022 (JP) 2022-090891

(51) Int. Cl. C09K 5/14; C08G 65/26; C08J 5/18; C08K 3/08; C08K 9/02

(52) U.S. Cl. CPC C09K 5/14; C08G 65/2615; C08J 5/18; C08K 3/08; C08K 9/02; C08J 2371/00; C08K 2003/0837; C08K 2003/085; C08K 2201/001; C08K 2201/014

(57) ABSTRACT

A thermally conductive composition including a curable component, a curing agent configured to cure the curable component, and a metallic filler is provided. The metallic filler contains thermally conductive particles and low-melting-point metallic particles. A volume average particle diameter of the thermally conductive particles is greater than a volume average particle diameter of the low-melting-point metallic particles. A melting point of the low-melting-point metallic particles is lower than a thermal curing treatment temperature of the thermally conductive composition.

### TECHNICAL FIELD

The present invention relates to a thermally conductive composition and a thermally conductive sheet.

### BACKGROUND ART

For a need to dissipate heat radiated by a Light-Emitting Diode (LED) chip, an Integrated Circuit (IC) chip, or the like mounted on a heat dissipation substrate to a heat sink via the heat dissipation substrate, the heat dissipation substrate and the heat sink hitherto have been bonded using a thermally conductive composition.

In order for the thermally conductive composition to satisfy a high thermal conductivity and a low thermal resistance, it is necessary to fill the thermally conductive composition with a metallic filler to a high level. However, this is problematic in that the fluidity of the composition is reduced when the composition is a liquid composition, or in that a sheet in a case of the composition being formed in a sheet shape is hard and has a low followability, to increase an interfacial resistance.

In order to solve the problem, for example, a proposed thermally conductive adhesive contains: a thermosetting adhesive containing a curable component and a curing agent; and a metallic filler dispersed in the thermosetting adhesive, wherein the metallic filler contains a silver powder and a solder powder, wherein the solder powder exhibits a melting temperature lower than the thermal curing treatment temperature of the thermally conductive adhesive and reacts with the silver powder at the thermal curing treatment conditions of the thermosetting adhesive to produce a high-melting-point solder alloy that exhibits a melting point higher than the melting temperature of the solder powder, wherein the curing agent is a curing agent having a flux activity on the metallic filler, wherein the curable component is a glycidyl ether-type epoxy resin, and wherein the curing agent is a monoacid anhydride of tricarboxylic acid (for example, see PTL 1).

### CITATION LIST

### Patent Literature

### [PTL 1] Japanese Patent No. 5796242

### SUMMARY OF THE INVENTION

### Technical Problem

However, according to the existing technique described in PTL 1, a network of the high-melting-point solder alloy, formed of silver particles having a small average particle diameter being mutually joined via the solder powder having a large average particle diameter, cannot satisfy a high thermal conductivity and a low thermal resistance because the content of the solder powder having a low thermal conductivity is greater than the content of the silver particles on a volume ratio basis. Moreover, use of the low-melting-point solder powder is problematic in that a resin layer is formed on the surface of an interfacial material to reduce the thermal conductivity, if the interfacial material is a material that cannot be easily wetted by the solder powder that has melted.

The present invention aims for solving the existing various problems described above, and achieving an object described below. That is, an object of the present invention is to provide a thermally conductive composition and a thermally conductive sheet that can realize a high thermal conductivity and a low thermal resistance.

### Solution to the Problem

Means for solving the problems described above are as follows.

<1> A thermally conductive composition, including:

a curable component;

a curing agent configured to cure the curable component; and

a metallic filler,

wherein the metallic filler contains thermally conductive particles and low-melting-point metallic particles,

a volume average particle diameter of the thermally conductive particles is greater than a volume average particle diameter of the low-melting-point metallic particles, and

a melting point of the low-melting-point metallic particles is lower than a thermal curing treatment temperature of the thermally conductive composition.

<2> The thermally conductive composition according to <1>,

wherein a ratio (A/B) of the volume average particle diameter A of the thermally conductive particles to the volume average particle diameter B of the low-melting-point metallic particles is 2 or greater.

<3> The thermally conductive composition according to <1> or <2>,

wherein a filling proportion of the metallic filler by volume is 50% by volume or greater.

<4> The thermally conductive composition according to any one of <1> to <3>,

wherein a ratio (A/B) of a volume A of the thermally conductive particles to a volume B of the low-melting-point metallic particles is 1 or greater.

<5> The thermally conductive composition according to any one of <1> to <4>, further including:

a polymer having at least one structure selected from a polybutadiene structure, a polysiloxane structure, a poly (meth) acrylate structure, a polyalkylene structure, a polyalkylene oxy structure, a polyisoprene structure, a polyisobutylene structure, a polyamide structure, and a polycarbonate structure in a molecule.

<6> The thermally conductive composition according to any one of <1> to <5>,

wherein the thermally conductive particles are at least any selected from copper particles, silver-coated particles, and silver particles.

<7> The thermally conductive composition according to any one of <1> to <6>,

wherein the low-melting-point metallic particles contain Sn, and at least one selected from Bi, Ag, Cu, and In.

<8> The thermally conductive composition according to any one of <1> to <7>,

wherein the low-melting-point metallic particles react with the thermally conductive particles under a thermal curing treatment condition of the thermally conductive composition to become an alloy that exhibits a melting point higher than the melting point of the low-melting-point metallic particles.

<9> The thermally conductive composition according to any one of <1> to <8>,

wherein the curing agent has a flux activity on the metallic filler.

<10> The thermally conductive composition according to any one of <1> to <9>,

wherein a ratio (C/D) of an equivalent weight C of the curable component to an equivalent weight D of the curing agent is 0.5 or greater and 3 or less.

<11> The thermally conductive composition according to any one of <1> to <10>,

wherein the curable component is at least any selected from oxirane ring compounds and oxetane compounds.

<12> The thermally conductive composition according to any one of <1> to <11>,

wherein the curable component is an oxetane compound, and the curing agent is glutaric acid.

<13> A thermally conductive sheet,

the thermally conductive sheet being a sheet made of the thermally conductive composition of any one of <1> to <12>.

### Advantageous Effects of the Invention

The present invention can solve the existing various problems described above, achieve an object described above, and provide a thermally conductive composition and a thermally conductive sheet that can realize a high thermal conductivity and a low thermal resistance.

### BRIEF DESCRIPTION OF THE DRAWINGS

FIG. 1 is a schematic cross-sectional view illustrating an example of a heat dissipation structure used in the present invention.

FIG. 2A is a cross-sectional image, captured using a semiconductor inspection microscope, of a polished surface obtained by polishing a cross-sectional surface obtained by cutting a cured product (interfaced by Cu) of a thermally conductive composition of Example 1.

FIG. 2B is a cross-sectional image, captured using a semiconductor inspection microscope, of a polished surface obtained by polishing a cross-sectional surface obtained by cutting a cured product (interfaced by Al) of the thermally conductive composition of Example 1.

FIG. 3A is a cross-sectional image, captured using a semiconductor inspection microscope, of a polished surface obtained by polishing a cross-sectional surface obtained by cutting a cured product (interfaced by Cu) of a thermally conductive composition of Comparative Example 1.

FIG. 3B is a cross-sectional image, captured using a semiconductor inspection microscope, of a polished surface obtained by polishing a cross-sectional surface obtained by cutting a cured product (interfaced by Al) of the thermally conductive composition of Comparative Example 1.

### DESCRIPTION OF EMBODIMENTS

### (Thermally Conductive Composition)

A thermally conductive composition according to the present invention contains a curable component, a curing agent, and a metallic filler, preferably contains a polymer having at least one structure selected from a polybutadiene structure, a polysiloxane structure, a poly (meth) acrylate structure, a polyalkylene structure, a polyalkylene oxy structure, a polyisoprene structure, a polyisobutylene structure, a polyamide structure, and a polycarbonate structure in a molecule (hereinafter, referred to as a “specific polymer”), and further contains other components as needed.

### <Curable Component>

As the curable component, it is preferable to use at least any selected from oxirane ring compounds and oxetane compounds.

### Oxirane Ring Compound

The oxirane ring compound is a compound containing an oxirane ring. Examples of the oxirane ring compound include epoxy resins.

The epoxy resin is not particularly limited and may be appropriately selected in accordance with the intended purpose. Examples of the epoxy resin include glycidyl ether-type epoxy resins, phenol novolac-type epoxy resins, cresol novolac-type epoxy resins, bisphenol A-type epoxy resins, tris phenol-type epoxy resins, tetraphenol-type epoxy resins, phenol-xylylene-type epoxy resins, naphthol-xylylene-type epoxy resins, phenol-naphthol-type epoxy resins, phenol-dicyclopentadiene-type epoxy resins, alicyclic epoxy resins, and aliphatic epoxy resins. These epoxy resins may be used alone or in combination of two or more.

### Oxetane Compound

The oxetane compound is a compound containing an oxetanyl group, and may be an aliphatic compound, an alicyclic compound, or an aromatic compound.

The oxetane compound may be a monofunctional oxetane compound containing only one oxetanyl group, or may be a multifunctional oxetane compound containing two or more oxetanyl groups.

The oxetane compound is not particularly limited and may be appropriately selected in accordance with the intended purpose. Examples of the oxetane compound include 3,7-bis(3-oxetanyl)-5-oxa-nonane, 1,4-bis[(3-ethyl-3-oxetanylmethoxy)methyl]benzene, 1,2-bis[(3-ethyl-3-oxetanylmethoxy)methyl]ethane, 1,3-bis[(3-ethyl-3-oxetanylmethoxy)methyl]propane, ethylene glycol bis(3-ethyl-3-oxetanylmethyl)ether, triethylene glycol bis(3-ethyl-3-oxetanylmethyl)ether, tetraethylene glycol bis(3-ethyl-3-oxetanylmethyl)ether, 1,4-bis(3-ethyl-3-oxetanylmethoxy)butane, 1,6-bis(3-ethyl-3-oxetanylmethoxy)hexane, 3-ethyl-3-(phenoxy)methyloxetane, 3-ethyl-3-(cyclohexyloxymethyl)oxetane, 3-ethyl-3-(2-ethylhexyloxymethyl)oxetane, 3-ethyl-3-hydroxymethyloxetane, 3-ethyl-3-(chloromethyl)oxetane, 3-ethyl-3 {[(3-ethyloxetan-3-yl)methoxy]methyl}oxetane, xylylene bis oxetane, 4,4′-bis [(3-ethyl-3-oxetanyl)methoxymethyl]biphenyl (OXBP), isophthalic acid bis[(3-ethyl-3-oxetanyl)methyl]ester (OXIPA), and the like. These oxetane compounds may be used alone or in combination of two or more.

As the oxetane compound, a commercially available product may be used. Examples of the commercially available product include “ARON OXETANE (registered trademark)” series sold by Toagosei Co., Ltd., “ETERNACOLL (registered trademark)” series sold by Ube Industries, Ltd., and the like.

Among the oxirane ring compounds and the oxetane compounds, glycidyl ether-type epoxy resins, phenol novolac-type epoxy resins, cresol novolac-type epoxy resins, phenol-dicyclopentadiene-type epoxy resins, bisphenol A-type epoxy resins, aliphatic epoxy resins, 4,4′-bis [(3-ethyl-3-oxetanyl)methoxymethyl]biphenyl (OXBP), and isophthalic acid bis[(3-ethyl-3-oxetanyl) methyl]ester (OXIPA) are preferable.

The content of the curable component is not particularly limited, may be appropriately selected in accordance with the intended purpose, and is preferably 0.5% by mass or greater and 60% by mass or less relative to the whole amount of the thermally conductive composition.

### <Curing Agent>

The curing agent is a curing agent that matches the curable component. Examples of the curing agent include polyaddition-type curing agents such as acid anhydride-based curing agents, aliphatic amine-based curing agents, aromatic amine-based curing agents, phenol-based curing agents, mercaptan-based curing agents, and the like, and catalyst-type curing agents such as imidazole and the like. These curing agents may be used alone or in combination of two or more. Among these curing agents, an acid anhydride-based curing agent is preferable. When the curable component is an epoxy resin, an acid anhydride-based curing agent is preferable because it is free of gas emission during thermal curing, can realize a long potlife when mixed with the epoxy resin, and can realize a favorable balance in electrical properties, chemical properties, and mechanical properties of a cured product to be obtained.

Examples of the acid anhydride-based curing agent include cyclohexane-1,2-dicarboxylic anhydride, monoacid anhydrides of tricarboxylic acid, and the like. Examples of the monoacid anhydride of tricarboxylic acid include cyclohexane-1,2,4-tricarbocylic acid-1,2-acid anhydride, and the like.

As the curing agent, one that has a flux activity is preferable in terms of improving the ability of low-melting-point metallic particles, which have melted, to wet thermally conductive particles. Examples of the method for making the curing agent to exhibit a flux activity include a method of introducing a protonic acid group such as a carboxy group, a sulfonyl group, a phosphoric acid group, or the like into the curing agent by a publicly known method, and the like. Among these, it is preferable to introduce a carboxy group in terms of reactivity with an epoxy resin or an oxetane compound serving as the curable component. Examples of such curing agents include carboxyl group-containing organic acids such as glutaric acid, succinic acid, and the like. The curing agent may be a modified compound of glutaric anhydride or succinic anhydride, may be organic acid metal salts such as silver glutarate and the like, or may be the like.

The content of the curing agent is not particularly limited, may be appropriately selected in accordance with the intended purpose, yet is preferably 0.1% by mass or greater and 30% by mass or less relative to the whole amount of the thermally conductive composition.

In the present invention, it is preferable that the curable component is an oxetane compound and that the curing agent is glutaric acid, because a higher thermal conductivity can be realized.

The ratio (C/D) of the equivalent weight C of the curable component to the equivalent weight D of the curing agent varies depending on the types of the curable component and the curing agent used and cannot be defined flatly, yet is preferably 0.5 or greater and 3 or less, more preferably 0.5 or greater and 2 or less, and more preferably 0.7 or greater and 1.5 or less.

When the equivalent weight ratio (C/D) is 0.5 or greater and 3 or less, there is an advantage that in thermal curing of the thermally conductive composition, low-melting-point metallic particles can sufficiently melt and form a network.

### <Metallic Filler>

The metallic filler contains thermally conductive particles and low-melting-point metallic particles.

### Thermally Conductive Particles

As the thermally conductive particles, at least any selected from copper particles, silver-coated particles, and silver particles are preferable.

Examples of the silver-coated particles include silver-coated copper particles, silver-coated nickel particles, silver-coated aluminum particles, and the like.

The shape of the thermally conductive particles is not particularly limited and may be appropriately selected in accordance with the intended purpose. Examples of the shape include a spherical shape, a flat shape, a particulate shape, an acicular shape, and the like.

The volume average particle diameter of the thermally conductive particles is preferably 10 μm or greater and 300 μm or less, and more preferably 20 μm or greater and 100 μm or less. When the volume average particle diameter of the thermally conductive particles is 10 μm or greater and 300 μm or less, it is possible to make the volume ratio of the thermally conductive particles to the low-melting-point metallic particles high, and to realize a high thermal conductivity and a low thermal resistance of the thermally conductive composition.

The volume average particle diameter can be measured using, for example, a laser diffraction/scattering-type particle diameter distribution analyzer (instrument name: Microtrac MT3300EXII).

Low-melting-point Metallic Particles

As the low-melting-point metallic particles, it is preferable to use solder particles prescribed by Japanese Industrial Standards (JIS) Z3282-1999.

Examples of the solder particles include Sn—Pb-based solder particles, Pb—Sn—Sb-based solder particles, Sn—Sb-based solder particles, Sn—Pb—Bi-based solder particles, Sn—Bi-based solder particles, Sn—Bi—Ag-based solder particles, Sn—Cu-based solder particles, Sn—Pb—Cu-based solder particles, Sn—In-based solder particles, Sn—Ag-based solder particles, Sn—Pb—Ag-based solder particles, Pb—Ag-based solder particles, Sn—Ag—Cu-based solder particles, and the like. These types of solder particles may be used alone or in combination of two or more.

Among these types of solder particles, solder particles containing Sn and at least one selected from Bi, Ag, Cu, and In are preferable, and Sn—Bi-based solder particles, Sn—Bi—Ag-based solder particles, Sn—Ag—Cu-based solder particles, and Sn—In-based solder particles are more preferable.

The shape of the low-melting-point metallic particles is not particularly limited and may be appropriately selected in accordance with the intended purpose. Examples of the shape include a spherical shape, a flat shape, a particulate shape, an acicular shape, and the like.

The melting point of the low-melting-point metallic particles is preferably 100°° C. or higher and 250° C. or lower, and more preferably 120° C. or higher and 200° C. or lower.

It is preferable that the melting point of the low-melting-point metallic particle is lower than the thermal curing treatment temperature of the thermally conductive composition, because the low-melting-point metallic particles that have melted can form a network (a metallic continuous phase) via the thermally conductive particles in a cured product of the thermally conductive composition, and can realize a high thermal conductivity and a low thermal resistance.

By the low-melting-point metallic particles reacting with the thermally conductive particles under the thermal curing treatment condition of the thermally conductive composition to become an alloy exhibiting a melting point higher than that of the low-melting-point metallic particles, it is possible to inhibit melting at a high temperature and to improve reliability. Moreover, the heat fastness of a cured product of the thermally conductive composition is improved.

The thermal curing treatment of the thermally conductive composition is performed, for example, at a temperature of 150° C. or higher and 200° C. for 30 minutes or longer and 2 hours or shorter.

The volume average particle diameter of the low-melting-point metallic particles is preferably 10μm or less and more preferably 1 μm or greater and 5 μm or less. When the volume average particle diameter of the low-melting-point metallic particles is 10 μm or less, it is possible to make the volume ratio of the low-melting-point metallic particles to the thermally conductive particles low, and to realize a high thermal conductivity and a low thermal resistance of the thermally conductive composition.

The volume average particle diameter of the low-melting-point metallic particles can be measured in the same manner as measuring the volume average particle diameter of the thermally conductive particles described above.

It is preferable that the volume average particle diameter of the thermally conductive particles is greater than the volume average particle diameter of the low-melting-point metallic particles, and the ratio (A/B) of the volume average particle diameter A of the thermally conductive particles to the volume average particle diameter B of the low-melting-point metallic particles is preferably 2 or greater, more preferably 3 or greater, and yet more preferably 5 or greater. The upper limit of the volume average particle diameter ratio (A/B) is preferably 20 or less and more preferably 10 or less.

When the low-melting-point metallic particles having a volume average particle diameter smaller than that of the thermally conductive particles are used, the thermally conductive particles become the main component in the thermally conductive composition, and the low-melting-point metallic particles existing between the thermally conductive particles and the thermally conductive particles melt and alloy with the thermally conductive particles in response to being heated, to form a network. Hence, it is possible to realize a high thermal conductivity and a low thermal resistance of the thermally conductive composition.

The ratio (A/B) of the volume A of the thermally conductive particles to the volume B of the low-melting-point metallic particles in the thermally conductive composition is preferably 1 or greater, more preferably 1.5 or greater, and yet more preferably 2 or greater. The upper limit of the volume ratio (A/B) is preferably 5 or less, more preferably 4 or less, and yet more preferably 3 or less.

When the volume ratio (A/B) is 1 or greater, the thermally conductive particles having a volume average particle diameter greater than that of the low-melting-point metallic particles account for a greater proportion by volume and can inhibit fluidization of the low-melting-point metallic particles that have melted. Moreover, the materials are not easily detached from an interface that is not easily wetted by the low-melting-point metallic particles (the interface being, e.g., aluminum). Hence, it is possible to inhibit the interfacial material from having any impact, and to improve the choice of the interfacial material.

The filling proportion of the metallic filler by volume is preferably 50% by volume or greater, more preferably 60% by volume or greater, yet more preferably 70% by volume or greater, and particularly preferably 75% by volume or greater. The upper limit of the filling proportion of the metallic filler by volume is preferably 90% by volume or less and more preferably 85% by volume or less.

When the filling proportion of the metallic filler by volume is 50% by volume or greater, it is possible to realize a high thermal conductivity and a low thermal resistance of the thermally conductive composition.

### <Specific Polymer>

It is preferable that the thermally conductive composition according to the present invention contains a specific polymer that imparts flexibility and properties of a sheet.

As the specific polymer, a polymer having at least one structure selected from a polybutadiene structure, a polysiloxane structure, a poly(meth)acrylate structure, a polyalkylene structure, a polyalkylene oxy structure, a polyisoprene structure, a polyisobutylene structure, a polyamide structure, and a polycarbonate structure in a molecule is used.

It is preferable that the specific polymer has at least one structure selected from, for example, a polybutadiene structure possessed by polybutadiene, hydrogenated polybutadiene, and the like, a polysiloxane structure possessed by silicone rubbers and the like, a poly(meth)acrylate structure, a polyalkylene structure (a polyalkylene structure containing from 2 through 15 carbon atoms is preferable, a polyalkylene structure containing from 3 through 10 carbon atoms is more preferable, and a polyalkylene structure containing from 5 through 6 carbon atoms is yet more preferable), a polyalkylene oxy structure (a polyalkylene oxy structure containing from 2 through 15 carbon atoms is preferable, a polyalkylene oxy structure containing from 3 through 10 carbon atoms is more preferable, and a polyalkylene oxy structure containing from 5 through 6 carbon atoms is yet more preferable), a polyisoprene structure, a polyisobutylene structure, and a polycarbonate structure. It is preferable that the specific polymer has at least one structure selected from a polybutadiene structure, a polysiloxane structure, a poly (meth) acrylate structure, a polyisoprene structure, a polyisobutylene structure, and a polycarbonate structure. It is more preferable that the specific polymer has at least one structure selected from a polybutadiene structure, a polyisoprene structure, and a polycarbonate structure.

It is preferable that the specific polymer has a high molecular weight in order to exhibit flexibility. The number average molecular weight (Mn) of the specific polymer is preferably 1,000 or greater and 1,000,000 or less, and more preferably 5,000 or greater and 900,000 or less.

The number average molecular weight (Mn) is a number average molecular weight in terms of polystyrene measured using Gel Permeation Chromatography (GPC).

It is preferable to select the specific polymer from polymers having a glass transition temperature (Tg) of 25° C. or lower and polymers that are liquid at 25° C., in order for the specific polymer to exhibit flexibility.

The glass transition temperature of the polymer having the glass transition temperature (Tg) of 25° C. or lower is preferably 20° C. or lower and more preferably 15° C. or lower. The lower limit of the glass transition temperature is not particularly limited, may be appropriately selected in accordance with the intended purpose, yet is preferably −15° C. or higher.

As the polymer that is liquid at 25° C., a polymer that is liquid at 20° C. or lower is preferable, and a polymer that is liquid at 15° C. or lower is more preferable.

It is preferable that the specific polymer contains a functional group that is reactive with the curable component described above, in order to improve the mechanical strength of a cured product. The functional group that is reactive with the curable component encompasses a functional group that appears in response to heating.

The functional group that is reactive with the curable component is one or more functional groups selected from the group consisting of a hydroxy group, a carboxy group, an acid anhydride group, a phenolic hydroxyl group, an epoxy group, an isocyanate group, and a urethane group. Among these functional groups, a hydroxy group, an acid anhydride group, a phenolic hydroxyl group, an epoxy group, an isocyanate group, and an urethane group are preferable, a hydroxy group, an acid anhydride group, a phenolic hydroxyl group, and an epoxy group are more preferable, and a phenolic hydroxyl group is particularly preferable.

A preferable embodiment of the specific polymer is a butadiene resin. As the butadiene resin, a butadiene resin that is liquid at 25° C. or has a glass transition temperature of 25° C. or lower is preferable, at least one selected from the group consisting of a hydrogenated polybutadiene skeleton-containing resin, a hydroxy group-containing butadiene resin, a phenolic hydroxy group-containing butadiene resin, a carboxy group-containing butadiene resin, an acid anhydride group-containing butadiene resin, an epoxy group-containing butadiene resin, an isocyanate group-containing butadiene resin, and a urethane group-containing butadiene resin is more preferable, and a phenolic hydroxyl group-containing butadiene resin is yet more preferable.

Examples of the hydrogenated polybutadiene skeleton-containing resin include a hydrogenated polybutadiene skeleton-containing epoxy resin, and the like.

Examples of the phenolic hydroxyl group-containing butadiene resin include a resin having a polybutadiene structure and containing a phenolic hydroxyl group, and the like.

Here, the “butadiene resin” is a resin containing a polybutadiene structure. The polybutadiene structure may be contained in the main chain or a side chain of the resin. The butadiene structure may be partially or entirely hydrogenated.

The “hydrogenated polybutadiene skeleton-containing resin” is a resin in which the polybutadiene skeleton is at least partially hydrogenated, and does not need to be a resin in which the polybutadiene skeleton is completely hydrogenated.

The number average molecular weight (Mn) of the butadiene resin is preferably from 1,000 through 100,000, more preferably from 5,000 through 50,000, yet more preferably from 7,500 through 30,000, and particularly preferably from 10,000 through 15,000.

The number average molecular weight (Mn) of the butadiene resin is a number average molecular weight in terms of polystyrene measured using Gel Permeation Chromatography (GPC).

A functional group equivalent weight of the butadiene resin in case of the butadiene resin containing a functional group is preferably from 100 through 10,000 and more preferably from 200 through 5,000. The functional group equivalent weight is the number of grams in a resin containing 1 gram equivalent weight of functional group. For example, an epoxy equivalent weight can be measured according to JIS K7236. A hydroxyl group equivalent weight can be calculated by dividing the molecular weight of KOH by a hydroxyl value measured according to JIS K1557-1.

As the butadiene resin, a commercially available product may be used. Examples of the commercially available product include “Ricon 657” (epoxy group-containing polybutadiene), “Ricon 130MA8”,“Ricon 130MA13”, “Ricon 130MA20”, “Ricon 131MA5”,“Ricon 131MA10”, “Ricon 131MA17”, “Ricon 131MA20”, and “Ricon 184MA6” (acid anhydride group-containing polybutadiene) available from Cray Valley Co., Ltd.; “JP-100”, “JP-200” (epoxylated polybutadiene), “GQ-1000” (hydroxyl group and carboxy group-incorporated polybutadiene), “G-1000”, “G-2000”, “G-3000” (polybutadiene containing hydroxyl groups at both ends), “GI-1000”, “GI-2000”, and “GI-3000” (hydrogenated polybutadiene containing hydroxyl groups at both ends) available from Nippon Soda Co., Ltd.; “PB3600”, “PB4700” (a polybutadiene skeleton epoxy compound), “EPOFRIEND A1005”, “EPOFRIEND A1010”, and “EPOFRIEND A1020” (an epoxy compound of a styrene/butadiene/styrene block copolymer) available from Daicel Corporation; “FCA-061L” (a hydrogenated polybutadiene skeleton epoxy compound) and “R-45EPT” (a polybutadiene skeleton epoxy compound) available from Nagase ChemteX Corporation, and the like.

As another preferable embodiment of the specific polymer, a resin having an imide structure may be used. Examples of the resin having an imide structure include polybutadiene containing a hydroxyl group at an end, linear polyimide made of a diisocyanate compound and a tetrabasic acid anhydride (polyimide described in Japanese Patent Application Laid-Open No. 2006-37083 and International Publication No. WO 2008/153208), and the like.

The content proportion of a polybutadiene structure in the polyimide resin is preferably from 60% b mass through 95% by mass and more preferably from 75% by mass through 85% by mass. As for the details of the polyimide resin, for example, the descriptions in Japanese Patent Application Laid-Open No. 2006-37083 and International Publication No. WO 2008/153208 may be referenced.

A preferable embodiment of the specific polymer is an isoprene resin. Specific examples of the isoprene resin include “KL-610” and “KL-613” available from Kuraray Co., Ltd., and the like. Here, the “isoprene resin” is a resin containing a polyisoprene structure. The polyisoprene structure may be contained in the main chain or a side chain of the resin.

A preferable embodiment of the specific polymer is a carbonate resin. As the carbonate resin, a carbonate resin having a glass transition temperature of 25° C. or lower is preferable, and one or more resins selected from the group consisting of a hydroxy group-containing carbonate resin, a phenolic hydroxyl group-containing carbonate resin, a carboxy group-containing carbonate resin, an acid anhydride group-containing carbonate resin, an epoxy group-containing carbonate resin, an isocyanate group-containing carbonate resin, and a urethane group-containing carbonate resin are more preferable.

Here, the “carbonate resin” is a resin containing a polycarbonate structure. The polycarbonate structure may be contained in the main chain or a side chain of the resin.

The number average molecular weight (Mn) of the carbonate resin, and the functional group equivalent weight of the carbonate resin in a case of the carbonate resin containing a functional group are the same as those of the butadiene resin, and preferable ranges of these values are also the same.

As the carbonate resin, a commercially available product may be used. Examples of the commercially available product include “T6002” and “T6001” (polycarbonate diol) available from Asahikasei Chemicals Corporation; “C-1090”, “C-2090”, and “C-3090” (polycarbonate diol) available from Kuraray Co., Ltd., and the like.

Polycarbonate containing a hydroxyl group at an end, and linear polyimide made of a diisocyanate compound and a tetrabasic acid anhydride may also be used. The content proportion of the polycarbonate structure in the polyimide resin is preferably from 60% by mass through 95% by mass and more preferably from 75% by mass through 85% by mass. As for the details of the polyimide resin, for example, the descriptions in International Publication No. WO 2016/129541, the contents of which are incorporated herein, may be referenced.

Another preferable embodiment of the specific polymer is an acrylic resin. As the acrylic resin, an acrylic resin having a glass transition temperature (Tg) of 25° C. or lower is preferable, and at least one resin selected from the group consisting of a hydroxy group-containing acrylic resin, a phenolic hydroxyl group-containing acrylic resin, a carboxy group-containing acrylic resin, an acid anhydride group-containing acrylic resin, an epoxy group-containing acrylic resin, an isocyanate group-containing acrylic resin, and a urethane group-containing acrylic resin is more preferable.

Here, the “acrylic resin” is a resin containing a poly (meth) acrylate structure. The poly (meth) acrylate structure may be contained in the main chain or side chain of the resin.

The number average molecular weight (Mn) of the acrylic resin is preferably from 10,000 through 1,000,000, and more preferably from 30,000 through 900,000.

Here, the number average molecular weight (Mn) of the acrylic resin is a number average molecular weight in terms of polystyrene measured using Gel Permeation Chromatography (GPC).

The functional group equivalent weight of the acrylic resin in a case of the acrylic resin containing a functional group is preferably from 1,000 through 50,000 and more preferably from 2,500 through 30,000.

As the acrylic resin, a commercially available product may be used. Examples of the commercially available product include TEISANRESIN “SG-70L”, “SG-708-6”, “WS-023”, “SG-700AS”, and “SG-280TEA” (carboxy group-containing acrylic acid ester copolymer resins, having an acid value of from 5 mgKOH/g through 34 mgKOH/g, a weight average molecular weight of from 400,000 through 900,000, and Tg of from −30° C. through 5° C.), “SG-80H”, “SG-80H-3”, and “SG-P3” (epoxy group-containing acrylic acid ester copolymer resins, having an epoxy equivalent weight of from 4,761 g/eq through 14,285 g/eq, a weight average molecular weight of from 350,000 through 850, 000, and Tg of from 11° C. through 12°° C.), and “SG-600TEA” and “SG-790” (hydroxy group-containing acrylic acid ester copolymer resins, having a hydroxy value of from 20 mgKOH/g through 40 mgKOH/g, a weight average molecular weight of from 500,000through 1,200,000, and Tg of from-37° C. through-32° C.) available from Nagase ChemteX Corporation; “ME-2000” and “W-116.3” (carboxy group-containing acrylic acid ester copolymer resins), “W-197C” (a hydroxyl group-containing acrylic acid ester copolymer resin), and “KG-25” and “KG-3000” (epoxy group-containing acrylic acid ester copolymer resins) available from Negami Chemical Industrial Co., Ltd., and the like.

Preferable embodiments of the specific polymer are a siloxane resin, an alkylene resin, an alkylene oxy resin, and an isobutylene resin.

As the siloxane resin, a commercially available product may be used. Examples of the commercially available product include “SMP-2006”, “SMP-2003PGMEA”, and “SMP-5005PGMEA” available from Shin-Etsu Silicones, Ltd., polysiloxane containing an amine group at an end, linear polyimide made of a tetrabasic acid anhydride (International Publication No. WO 2010/053185), and the like. Here, the “siloxane resin” is a resin containing a polysiloxane structure. The polysiloxane structure may be contained in the main chain or a side chain of the resin.

As the alkylene resin and the alkylene oxy resin, commercially available products may be used. Examples of the commercially available products include: “PTXG-1000” and “PTXG-1800” available from Asahi Kasei Fibers Corporation); “YX-7180” (a resin containing an ether bond-containing alkylene structure) available from Mitsubishi Chemical Corporation; “EXA-4850-150”, “EXA-4816”, and “EXA-4822” available from DIC Corporation; “EP-4000”, “EP-4003”, “EP-4010”, and “EP-4011” available from ADEKA Corporation; “BEO-60E” and “BPO-20E” available from New Japan Chemical Co., Ltd.; “YL7175” and “YL7410” available from Mitsubishi Chemical Corporation, and the like.

Here, the “alkylene resin” is a resin containing a polyalkylene structure, and the “alkylene oxy resin” is a resin containing a polyalkylene oxy structure. The polyalkylene structure and the polyalkylene oxy structure may be contained in the main chain or a side chain of these resins.

As the isobutylene resin, a commercially available product may be used. Examples of the commercially available product include “IBSTAR-073T” (a styrene-isobutylene-styrene triblock copolymer) and “SIBSTAR-042D” (a styrene-isobutylene diblock copolymer) available from Kaneka Corporation, and the like. Here, the “isobutylene resin” is a resin containing a polyisobutylene structure. The polyisobutylene structure may be contained in the main chain or a side chain of the resin.

Preferable embodiments of the specific polymer include acrylic rubber particles, polyamide particles, silicone particles, and the like.

Specific examples of the acrylic rubber particles include particles of a resin obtained by chemically crosslinking a resin that exhibits a rubber elasticity such as acrylonitrile butadiene rubbers, butadiene rubbers, acrylic rubbers, or the like, to make the resin insoluble in an organic solvent and infusible. Specific examples of such acrylic rubber particles include XER-91 (available from JSR Corporation); STAFILOID AC3355, AC3816, AC3832, AC4030, AC3364, and IM101 (all available from Gantsu Kasei K.K.); PARALOID EXL2655 and EXL2602 (both available from KUREHA Corporation), and the like.

As the polyamide particles, any polyamide particles are acceptable as long as they have a flexible skeleton such as that of aliphatic polyamide such as nylon, of polyamideimide, and of the like.

Specific examples of the polyamide particles include VESTOSINT 2070 (available from Daicel-Huels), SP500 (available from Toray Industries, Inc.), and the like.

As the polymer having a polyamide structure (polyamide resin), a commercially available product may be used. Examples of the commercially available product include TOHMIDE 558, 560, and 535 (all available from T&K TOKA Corporation), Platamid HX2592, M1276, and H2544 (available form Arkema S.A.), and the like.

The content of the specific polymer is preferably 1% by mass or greater and 50% by mass or less, more preferably 1$ by mass or greater and 30% by mass or less, and yet more preferably 1% by mass or greater and 10% by mass or less relative to the whole amount of the thermally conductive composition.

### <Other Components>

The thermally conductive composition may contain other components as long as the effects of the present invention are not spoiled. The other components are not particularly limited and may be appropriately selected in accordance with the intended purpose. Examples of the other components include thermally conductive particles made of materials other than metals (e.g., aluminum nitride, alumina, carbon fiber, and the like), and additives (e.g., an antioxidant, an ultraviolet absorbent, a curing accelerator, a silane coupling agent, a leveling agent, a flame retardant, and the like).

It is possible to prepare the thermally conductive composition according to the present invention, by uniformly mixing the curable component, the curing agent, the metallic filler, and the specific polymer, and, as needed, the other components by a routine method.

The thermally conductive composition may be any selected from a thermally conductive sheet in a sheet state and a thermally conductive paste in a paste state (may also be referred to as a thermally conductive adhesive or a thermally conductive grease). Of these, a thermally conductive sheet is preferable in terms of ease with handling, and a thermally conductive paste is preferable in terms of costs.

### (Thermally Conductive Sheet)

A thermally conductive sheet according to the present invention is a sheet made of the thermally conductive composition according to the present invention.

The average thickness of the thermally conductive sheet is preferably 500 μm or less, more preferably 200 μm or less, and yet more preferably 100 μm or less in terms of reduction in thickness. The lower limit of the average thickness of the thermally conductive sheet is not particularly limited, may be appropriately selected in accordance with the intended purpose, and is preferably 5 μm or greater, more preferably 10 μm or greater, and yet more preferably 50 μm or greater.

The method for producing the thermally conductive sheet is not particularly limited and may be appropriately selected in accordance with the intended purpose. Examples of the method include (1) a method of curing the thermally conductive composition while being molded into a predetermined shape, and slicing the obtained thermally conductive molded product into a sheet shape, to produce a thermally conductive sheet, and (2) a method of forming a cured product layer containing a cured product of the thermally conductive composition over a release layer-added support, to produce a thermally conductive sheet. In the (2), the support is peeled when laminating the thermally conductive sheet over a heat dissipation substrate.

The thermally conductive composition and the thermally conductive sheet according to the present invention can be suitably used when forming a power LED module or a power IC module by bonding a heat dissipation substrate, which is mounted with an LED chip or an IC chip, with a heat sink.

Here, power LED modules include wire bonding-packaged types and flip chip-packaged types. Power IC modules include wire bonding-packaged types.

### <Heat Dissipation Structure>

A heat dissipation structure used in the present invention is formed of a heat generator, a thermally conductive material, and a heat dissipation member, and includes a cured product of the thermally conductive composition according to the present invention between the heat generator and the heat dissipation member.

The heat generator is not particularly limited and may be appropriately selected in accordance with the intended purpose. Examples of the heat generator include electronic parts such as a Central Processing Unit (CPU), a Micro Processing Unit (MPU), a Graphics Processing Unit (GPU), and the like.

The heat dissipation member is not particularly limited and may be appropriately selected as long as it is a structure configured to dissipate heat generated by an electronic part (heat generator). Examples of the heat dissipation member include a heat spreader, a heat sink, a vapor chamber, a heat pipe, and the like.

The heat spreader is a member configured to efficiently conduct heat of the electronic part to another part. The material of the heat spreader is not particularly limited and may be appropriately selected in accordance with the intended purpose. Examples of the material include copper, aluminum, and the like. The heat spreader typically has a flat plate shape.

The heat sink is a member configured to release heat of the electronic part into the air. The material of the heat sink is not particularly limited and may be appropriately selected in accordance with the intended purpose. Examples of the material include copper, aluminum, and the like. The heat sink includes, for example, a plurality of fins. For example, the heat sink includes a base portion, and the plurality of fins placed on one surface of the base portion to extend in a direction non-parallel with (e.g., a direction orthogonal to) the one surface.

The heat spreader and the heat sink are typically solid structures including no space inside.

The vapor chamber is a hollow structure. The internal space of the hollow structure is encapsulated with a volatile liquid. Examples of the vapor chamber include a hollow structured version of the heat spreader, a plate-shaped hollow structure such as a hollow structured version of the heat sink, and the like.

The heat pipe is a hollow structure having a cylindrical shape, an approximately cylindrical shape, or a flat tubular shape. The internal space of the hollow structure is encapsulated with a volatile liquid.

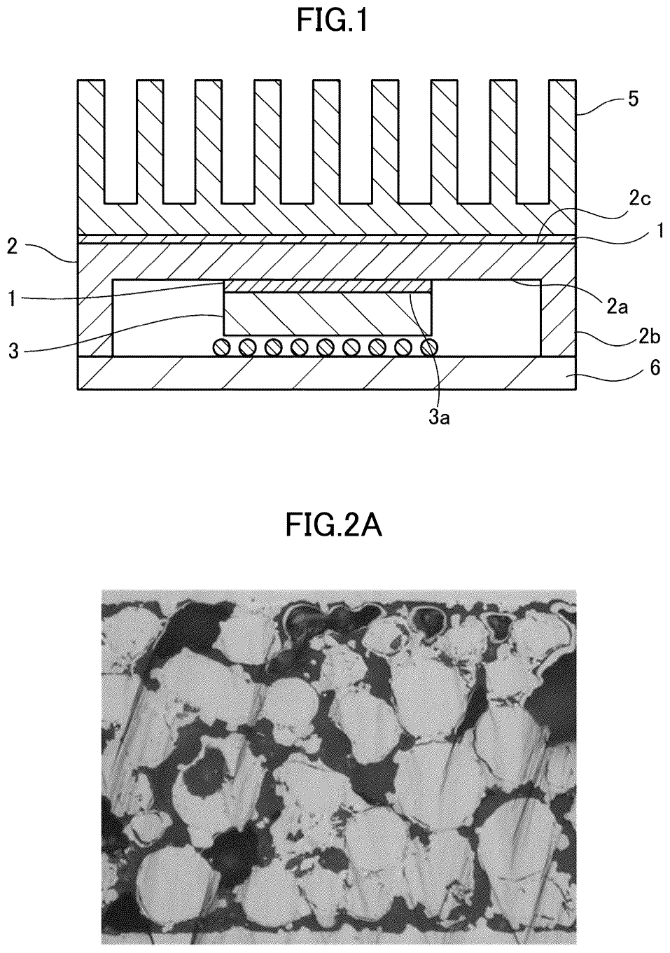

Here, FIG. 1 is a schematic cross-sectional view illustrating an example of a semiconductor device as a heat dissipation structure. A cured product (thermally conductive sheet) 1 of the thermally conductive composition according to the present invention is configured to dissipate heat generated by an electronic part 3 such as a semiconductor element or the like, and, as illustrated in FIG. 1, is secured to a principal surface 2a of the heat spreader 2 facing the electronic part 3 and sandwiched between the electronic part 3 and the heat spreader 2. The thermally conductive sheet 1 is also sandwiched between the heat spreader 2 and a heat sink 5. Together with the heat spreader 2, the thermally conductive sheet 1 forms a heat dissipation member configured to dissipate heat of the electronic part 3.

For example, the heat spreader 2 is formed in a square plate shape, and has the principal surface 2a facing the electronic part 3, and a side wall 2b provided in a standing state along the perimeter of the principal surface 2a. The heat spreader 2 is provided with the thermally conductive sheet 1 on the principal surface 2a enclosed within the side wall 2b, and is provided with the heat sink 5 on another surface 2c opposite to the principal surface 2a via the thermally conductive sheet 1. The heat spreader 2 having a higher thermal conductivity has a lower thermal resistance and absorbs heat of the electronic part 3 such as a semiconductor element or the like more efficiently. Hence, for example, the heat spreader 2 may be made of copper or aluminum having a good thermal conductivity.

The electronic part 3 is a semiconductor element such as a BGA or the like and is mounted on a wiring board 6. An end surface of the side wall 2b of the heat spreader 2 is also mounted on the wiring board 6. Hence, the electronic part 3 is surrounded by the side wall 2b while being spaced apart by a predetermined distance from the side wall 2b.

When the thermally conductive sheet 1 is bonded on the principal surface 2a of the heat spreader 2, the heat dissipation member configured to absorb heat generated by the electronic part 3 and dissipate the heat through the heat sink 5 is completed.

### EXAMPLES

The present invention will be described below by way of Examples. The present invention should not be construed as being limited to these Examples.

### Examples 1 to 12 and Comparative Examples 1 and 2

### <Preparation of Thermally Conductive Composition>

As in Table 1 to Table 4 below, the specified components in the specified contents were uniformly mixed using a stirrer (an AWATORI RENTARO rotation-revolution mixer, obtained from Thinky Corporation), to prepare thermally conductive compositions of Examples 1 to 12 and Comparative Examples 1 and 2. The contents of the components in Table 1 to Table 4 are in parts by mass.

### <Production of Cured Product>

Next, a 0.125 mm spacer, and each thermally conductive composition amounting to a diameter of 20 mm were sandwiched between two aluminum plates (A5052P) having a size of 30 mm×30 mm×2 mm, and cured in an oven at 150° C. for 60 minutes, to obtain a cured product (interfaced by Al) of each thermally conductive composition.

Next, “sheet property”, “network forming property”, and “thermal conductivity” of Examples 1 to 12 and Comparative Examples 1 and 2 were evaluated in the manners described below. The results are indicated in Table 1 to Table 4.

### <Sheet Property>

Each thermally conductive sheet obtained through drying at 100° C. for 15 minutes was folded by 45 degrees or 90 degrees, to visually observe the folded portion of each thermally conductive sheet and evaluate the sheet property according to the criteria listed below.

### [Evaluation Criteria]

A: No crack occurred in the folded portion of the folded thermally conductive sheet by folding by 90 degrees.

B: No crack occurred in the folded portion of the folded thermally conductive sheet by folding by 45 degrees.

C: A crack occurred in the folded portion of the folded thermally conductive sheet.

### <Network Forming Property>

The cured product (interfaced by Al) of each thermally conductive composition was cut, the obtained cross-section was polished, and an image of the polished surface was captured using a semiconductor inspection microscope (MX61L, obtained from Olympus Corporation), to observe presence or absence of a network (metallic continuous phase) made of the low-melting-point metallic particles and evaluate the network forming property according to the criteria listed below.

### [Evaluation Criteria]

A: The low-melting-point metallic particles completely melted and became joined to the thermally conductive particles.

B: The low-melting-point metallic particles partially melted and became joined to the thermally conductive particles.

C: The low-melting-point metallic particles did not melt.

### <Thermal Conductivity>

The cured product (interfaced by Al) of each thermally conductive composition, and a 0.125 mm spacer and each thermally conductive composition amounting to a diameter of 20 mm, which were sandwiched between two copper plates having a size of 30 mm×30 mm×2 mm were cured in an oven at 150° C. for 60 minutes, to measure the thermal resistance (° C·cm²/W) of a cured product (interfaced by Cu) of each thermally conductive composition according to a method compliant with ASTM-D5470. The thermal resistance of the cured product was a value calculated by subtracting the thermal resistance of the metal plate from the measured result. The thermal conductivity (W/m·K) was calculated based on the calculated thermal resistance and the thickness of the cured product, and evaluated according to the criteria listed below.

### [Evaluation Criteria]

A: The thermal conductivity was 11.0 W/m·K or higher.

B: The thermal conductivity was 8.0 W/m·K or higher and lower than 11.0 W/m·K.

C: The thermal conductivity was lower than 8.0 W/m·K.

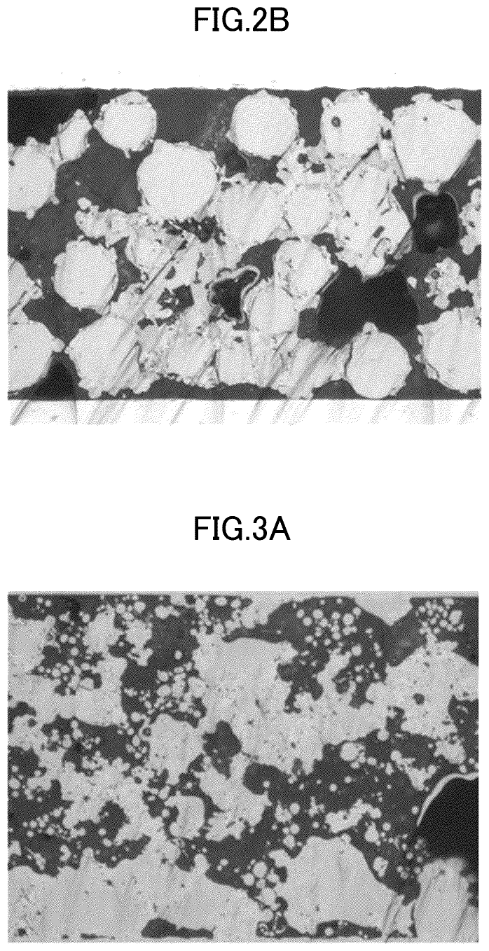

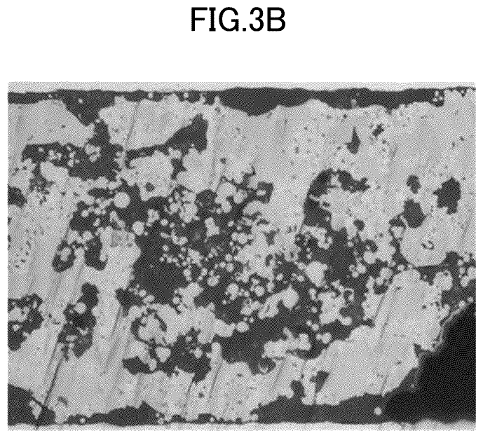

Next, the cured products (interfaced by Cu) of the thermally conductive compositions of Example 1 and Comparative Example 1 were cut, the obtained cross-sections were polished, and images of the polished surfaces were captured using a semiconductor inspection microscope (MX61L, obtained from Olympus Corporation). The images of the cross-sections are illustrated in FIG. 2A and FIG. 3A.

The cured products (interfaced by Al) of the thermally conductive compositions of Example 1 and Comparative Example 1 were cut, the obtained cross-sections were polished, and images of the polished surfaces were captured using a semiconductor inspection microscope (MX61L, obtained from Olympus Corporation). The images of the cross-sections are illustrated in FIG. 2B and FIG. 3B.

TABLE 1

| | | Ex. | | | | |
|---|---|---|---|---|---|---|
| | | 1 | 2 | 3 | 4 | 5 |
| Curable | AER9000 | 100 | 100 | 100 | 100 | 100 |
| component: C | | | | | | |
| Curing | MH700 | 50 | 50 | 50 | 50 | 50 |
| agent: D | | | | | | |
| Equivalent weight ratio (C/D) | | 0.86 | 0.86 | 0.86 | 0.86 | 0.86 |
| Thermally | Ag coated Cu (Dv = 40 μm) | 2,412 | 2,067 | — | 2,412 | 1,876 |
| conductive | Cu (Dv = 40 μm) | — | — | 2,372 | — | — |
| particles: A | Ag coated Cu (Dv = 5 μm) | — | — | — | — | — |
| | Cu (Dv = 5 μm) | — | — | — | — | — |
| Low- | Sn₅₈Bi₄₂ (Dv = 4 μm, | 976 | 1,301 | 976 | — | 759 |
| melting- | mp = 139° C.) | | | | | |
| point | Sn₅₈In₄₂ (Dv = 16 μm, | — | — | — | 833 | — |
| metallic | mp = 117° C.) | | | | | |
| particles: B | Sn₅₈Bi₄₂ (Dv = 20 μm, | — | — | — | — | — |
| | mp = 139° C.) | | | | | |
| Vol. Av. PTCL dia. ratio (A/B) | | 10 | 10 | 10 | 2.5 | 10 |
| Vol. ratio (A/B) | | 2.3 | 1.5 | 2.3 | 2.3 | 2.3 |
| Filling PROP of MTL. filler by Vol. (vol %) | | 75 | 75 | 75 | 75 | 70 |
| Evaluation | Network forming property | A | A | A | B | B |
| results | Thermal conductivity | A | B | A | A | B |
| | (interfaced by Cu) | | | | | |
| | Thermal conductivity | A | B | A | B | B |
| | (interfaced by Al) | | | | | |
| | Sheet property (drying | B | B | B | B | B |
| | at 100° C. for 15 min) | | | | | |

TABLE 2

| | | Ex. | |
|---|---|---|---|
| | | 6 | 7 |
| Curable | AER9000 | 100 | 100 |
| component: | | | |
| C | | | |
| Curing | MH700 | 50 | 40 |
| agent: D | | | |
| Equivalent weight ratio (C/D) | | 0.86 | 1.08 |
| Thermally | Ag coated Cu (Dv = 40 μm) | 804 | 2,248 |
| conductive | Cu (Dv = 40 μm) | — | — |
| particles: | Ag coated Cu (Dv = 5 μm) | — | — |
| A | Cu (Dv = 5 μm) | — | — |
| Low- | Sn₅₈Bi₄₂ (Dv = 4 μm, | 325 | 910 |
| melting- | mp = 139° C.) | | |
| point | Sn₅₈In₄₂ (Dv = 16 μm, | — | — |
| metallic | mp = 117° C.) | | |
| particles: | Sn₅₈Bi₄₂ (Dv = 20 μm, | — | — |
| B | mp = 139° C.) | | |
| Vol. Av. PTCL dia. ratio (A/B) | | 10 | 10 |
| Vol. ratio (A/B) | | 2.3 | 2.3 |
| Filling PROP of MTL. filler by Vol. (vol %) | | 50 | 75 |
| Evaluation | Network forming property | B | B |
| results | Thermal conductivity | B | B |
| | (interfaced by Cu) | | |
| | Thermal conductivity | B | B |
| | (interfaced by Al) | | |
| | Sheet property (drying | B | B |
| | at 100° C. for 15 min) | | |

TABLE 3

| | | Comp. Ex. | |
|---|---|---|---|
| | | 1 | 2 |
| Curable | AER9000 | 100 | 100 |
| component: | | | |
| C | | | |
| Curing | MH700 | 50 | 50 |
| agent: D | | | |
| Equivalent weight ratio (C/D) | | 0.86 | 0.86 |
| Thermally | Ag coated Cu (Dv = 40 μm) | — | — |
| conductive | Cu (Dv = 40 μm) | — | — |
| particles: | Ag coated Cu (Dv = 5 μm) | 1,034 | — |
| A | Cu (Dv = 5 μm) | — | 1,017 |
| Low- | Sn₅₈Bi₄₂ (Dv = 4 μm, | — | — |
| melting- | mp = 139° C.) | | |
| point | Sn₅₈In₄₂ (Dv = 16 μm, | — | — |
| metallic | mp = 117° C.) | | |
| particles: | Sn₅₈Bi₄₂ (Dv = 20 μm, | 2,277 | 2,277 |
| B | mp = 139° C.) | | |
| Vol. Av. PTCL dia. ratio (A/B) | | 0.25 | 0.25 |
| Vol. ratio (A/B) | | 0.43 | 0.43 |
| Filling PROP of MTL. filler by Vol. (vol %) | | 75 | 75 |
| Evaluation | Network forming property | A | A |
| results | Thermal conductivity | B | B |
| | (interfaced by Cu) | | |
| | Thermal conductivity | C | C |
| | (interfaced by Al) | | |
| | Sheet property (drying | B | B |
| | at 100° C. for 15 min) | | |

TABLE 4

| | | Ex. | | | | |
|---|---|---|---|---|---|---|
| | | 8 | 9 | 10 | 11 | 12 |
| Specific | LIR-410 | 105 | | | | |
| polymer | EPOFRIEND AT501 | | 30 | | | |
| | M1276 | | | 96 | 32 | 32 |
| Curable | AER9000 | 30 | 80 | 36 | | |
| component: C | OXBP | | | | 83 | |
| | OXIPA | | | | | 73 |
| Curing | MH700 | 15 | 40 | 18 | | |
| agent: D | Glutaric acid | | | | 31 | 31 |
| Equivalent weight ratio (C/D) | | 0.86 | 0.86 | 0.86 | 0.86 | 0.86 |
| Thermally | Ag coated Cu (Dv = 40 μm) | 2,412 | 2,412 | 2,412 | 2,412 | 2,412 |
| conductive | Cu (Dv = 40 μm) | — | — | — | — | — |
| particles: A | Ag coated Cu (Dv = 5 μm) | — | — | — | — | — |
| | Cu (Dv = 5 μm) | — | — | — | — | — |
| Low- | Sn₅₈Bi₄₂ (Dv = 4 μm, | 976 | 976 | 976 | 976 | 976 |
| melting- | mp = 139° C.) | | | | | |
| point | Sn₅₈In₄₂ (Dv = 16 μm, | — | — | — | — | — |
| metallic | mp = 117° C.) | | | | | |
| particles: B | Sn₅₈Bi₄₂ (Dv = 20 μm, | — | — | — | — | — |
| | mp = 139° C.) | | | | | |
| Vol. Av. PTCL dia. ratio (A/B) | | 10 | 10 | 10 | 10 | 10 |
| Vol. ratio (A/B) | | 2.3 | 2.3 | 2.3 | 2.3 | 2.3 |
| Filling PROP of MTL. filler by Vol. (vol %) | | 75 | 75 | 75 | 75 | 75 |
| Evaluation | Network forming | B | B | B | B | B |
| results | property | | | | | |
| | Thermal conductivity | A | A | A | A | A |
| | (interfaced by Cu) | | | | | |
| | Thermal conductivity | B | B | B | A | A |
| | (interfaced by Al) | | | | | |
| | Sheet property (drying | A | A | A | A | A |
| | at 100° C. for 15 min) | | | | | |

From the results of Table 4, it was revealed that Examples 8 to 12 in which a specific polymer was added achieved a better sheet folding resistance than that of Examples 1 to 7 in which no specific polymer was added.

Moreover, it was revealed that Examples 11and 12 in which an oxetane compound was used as a curable component and glutaric acid was used as a curing agent achieved a better thermal conductivity than that of Examples 8 to 10 in which an epoxy resin was used as a curable component and cyclohexane-1,2-dicarboxylic anhydride was used as a curing agent.

The details of the respective components in Table 1 to Table 4 are as follows.

Curable component

*AER9000: obtained from Asahi Kasei Corporation

*OXBP: obtained from UBE Corporation, 4,4′-bis[(3-ethyl-3-oxetanyl)methoxymethyl]biphenyl

*OXIPA: obtained from UBE Corporation, isophthalic acid bis [(3-ethyl-3-oxetanyl)methyl]ester

### Curing Agent

*MH-700: RIKACID MH-700, obtained from New Japan Chemical Co., Ltd., a liquid alicyclic acid anhydride containing 4-methyl HHMA (cyclohexane-1,2-dicarboxylic anhydride) as a main component

*Glutaric acid: obtained from Tokyo Chemical Industry C., Ltd., 1,3-propane dicarboxylic acid

Low-melting-point Metallic Particles (Solder Particles)

*Sn₅₈Bi₄₂: obtained from Mitsui Mining & Smelting Co., Ltd., having a volume average particle diameter Dv of 4 μm, and a melting point of 139° C.

*Sn₅₈In₄₂: obtained from 5N Plus Inc., having a volume average particle diameter Dv of 16 μm, and a melting point of 117° C.

*Sn₅₈Bi₄₂: obtained from Mitsui Mining & Smelting Co., Ltd., having a volume average particle diameter Dv of 20 μm, and a melting point of 139° C.

The volume average particle diameters Dv of the low-melting-point metallic particles were values measured using a laser diffraction/scattering-type particle diameter distribution analyzer (instrument name: Microtrac MT3300EXII).

### Thermally Conductive Particles

*Ag coated Cu particles: obtained from Fukuda Metal Foil & Powder Co., Ltd., having a volume average particle diameter Dv of 40 μm

*Ag coated Cu particles: obtained from Fukuda Metal Foil & Powder Co., Ltd., having a volume average particle diameter Dv of 5 μm

*Cu particles: obtained from Fukuda Metal

Foil & Powder Co., Ltd., having a volume average particle diameter Dv of 40 μm

*Cu particles: obtained from Fukuda Metal Foil & Powder Co., Ltd., having a volume average particle diameter Dv of 5 μm

The volume average particle diameters Dv of the thermally conductive particles were values measured using a laser diffraction/scattering-type particle diameter distribution analyzer (instrument name: Microtrac MT3300EXII).

### Specific Polymer

*LIR-410: KURAPRENE (registered trademark), obtained from Kuraray Co., Ltd., an isoprene-based liquid rubber

*EPOFRIEND AT501: obtained from Daicel Corporation, an epoxy compound of a styrene-butadiene block copolymer

*M1276: obtained from Arkema S.A., a polyamide compound

### INDUSTRIAL APPLICABILITY

The thermally conductive composition and the thermally conductive sheet according to the present invention can realize a high thermal conductivity and a low thermal resistance. Hence, they are suitably used on, for example, various electric devices of which the element operation efficiency, the lifetime, and the like may be adversely affected by temperature, such as CPUs, MPUs, power transistors, LEDs, laser diodes, various batteries (various secondary batteries such as lithium ion batteries and the like, various fuel batteries, capacitors, amorphous silicon, crystalline silicon, compound semiconductors, and various photovoltaic batteries such as wet solar cells and the like), and the like, and heat sources of heating devices, heat exchangers, heat piping of floor heating appliances, and the like that are required to utilize heat effectively.

The present international application claims priority to Japanese Patent Application No. 2021-146584 filed Sep. 9, 2021, and Japanese Patent Application No. 2022-090891 filed Jun. 3, 2022. The entire contents of Japanese Patent Application No. 2021-146584 and Japanese Patent Application No. 2022-090891 are incorporated herein by reference.

### REFERENCE SIGNS LIST

1 thermally conductive material (thermally conductive sheet)

2 heat dissipation member (heat spreader)

2a principal surface

3 heat generator (electronic part)

3a upper surface

5 heat dissipation member (heat sink)

6 wiring board

1. A thermally conductive composition, comprising:
a curable component;
a curing agent configured to cure the curable component; and
a metallic filler,
wherein the metallic filler contains thermally conductive particles and low-melting-point metallic particles,
a volume average particle diameter of the thermally conductive particles is greater than a volume average particle diameter of the low-melting-point metallic particles, and
a melting point of the low-melting-point metallic particles is lower than a thermal curing treatment temperature of the thermally conductive composition.

2. The thermally conductive composition according to claim 1,
wherein a ratio (A/B) of a volume average particle diameter A of the thermally conductive particles to a volume average particle diameter B of the low-melting-point metallic particles is 2 or greater.

3. The thermally conductive composition according to claim 1,
wherein a filling proportion of the metallic filler by volume is 50% by volume or greater.

4. The thermally conductive composition according to claim 1,
wherein a ratio (A/B) of a volume A of the thermally conductive particles to a volume B of the low-melting-point metallic particles is 1 or greater.

5. The thermally conductive composition according to claim 1, further comprising:
a polymer having at least one structure selected from a polybutadiene structure, a polysiloxane structure, a poly (meth) acrylate structure, a polyalkylene structure, a polyalkylene oxy structure, a polyisoprene structure, a polyisobutylene structure, a polyamide structure, and a polycarbonate structure in a molecule.

6. The thermally conductive composition according to claim 1,
wherein the thermally conductive particles are at least any selected from copper particles, silver-coated particles, and silver particles.

7. The thermally conductive composition according to claim 1,
wherein the low-melting-point metallic particles contain Sn, and at least one selected from Bi, Ag, Cu, and In.

8. The thermally conductive composition according to claim 1,
wherein the low-melting-point metallic particles react with the thermally conductive particles under a thermal curing treatment condition of the thermally conductive composition to become an alloy that exhibits a melting point higher than the melting point of the low-melting-point metallic particles.

9. The thermally conductive composition according to claim 1,
wherein the curing agent has a flux activity on the metallic filler.

10. The thermally conductive composition according to claim 1,
wherein a ratio (C/D) of an equivalent weight C of the curable component to an equivalent weight D of the curing agent is 0.5 or greater and 3 or less.

11. The thermally conductive composition according to claim 1,
wherein the curable component is at least any selected from oxirane ring compounds and oxetane compounds.

12. The thermally conductive composition according to claim 1,
wherein the curable component is an oxetane compound, and the curing agent is glutaric acid.

13. A thermally conductive sheet,
the thermally conductive sheet being a sheet made of the thermally conductive composition of claim 1.
